(19) United States
(12) Patent Application Publication
(10) Pub. No.: US 2026/0012140 A1
(43) Pub. Date: Jan. 8, 2026

(54) LINEARIZATION METHOD FOR POWER AMPLIFIER AND ELECTRONIC DEVICE THEREOF

(71) Applicant: LITE-ON TECHNOLOGY CORPORATION, TAIPEI CITY (TW)

(72) Inventor: Wen Chieh CHEN, Taipei City (TW)

(21) Appl. No.: 19/252,221

(22) Filed: Jun. 27, 2025

Related U.S. Application Data
(60) Provisional application No. 63/666,813, filed on Jul. 2, 2024.

(30) Foreign Application Priority Data
Jun. 18, 2025 (TW) 114122852

(51) Int. Cl. H03F 1/32; H03F 3/24

(52) U.S. Cl. CPC H03F 1/3247; H03F 3/24; H03F 2201/3233

(57) ABSTRACT

A linearization method for a power amplifier includes the following steps. An input signal and an error associated with the input signal are received. Fuzzy statistics is performed on the input signal and the error. A compensation value is calculated according to a fuzzy control table and a defuzzification equation. The compensation value is combined with the input signal to obtain an intermediate signal, and the intermediate signal is input into a power amplifier, so that the power amplifier outputs a first output signal. The first output signal from the power amplifier is fed back into an inverse model of an ideal power amplifier, so that the inverse model outputs a second output signal. A subtraction between the intermediate signal and the second output signal is calculated to obtain the error.

### CROSS REFERENCE TO RELATED APPLICATIONS

This application claims the benefit of U.S. provisional application No. 63/666,813, filed on Jul. 2, 2024, and Taiwan application No. 114122852 filed on Jun. 18, 2025, the entirety of which are incorporated by reference herein.

### BACKGROUND OF THE DISCLOSURE

### Field of the Disclosure

The disclosure relates to a power amplifier, and, in particular, it relates to a linearization method for a power amplifier and an electronic device thereof.

### Description of the Related Art

In the prior art, Digital Pre-Distortion (DPD) is used to perform linearization of power amplifiers (PA). DPD works by pre-distorting transmitted data in the digital domain to remove distortions caused by PA compression in the analog domain. In this way, DPD can double, or more than double, the PA power-added efficiency, driving the PA further into saturation while meeting linearity requirements.

However, since the inverse function of the nonlinear components in the input and output curves of a power amplifier needs to be calculated during the DPD process, the calculation process is very long and complicated, and requires huge computing resources. Therefore, how to simplify the linearization operation of a power amplifier has become an important issue.

### BRIEF SUMMARY OF THE DISCLOSURE

An embodiment of the disclosure provides a linearization method for a power amplifier. The linearization method includes the following steps. An input signal and an error associated with the input signal are received. Fuzzy statistical processing is performed on the input signal and the error. A compensation value is calculated according to a fuzzy control table and a defuzzification equation. The compensation value is combined with the input signal to obtain an intermediate signal, and the intermediate signal is input into a power amplifier, so that the power amplifier outputs a first output signal. The first output signal from the power amplifier is fed back into an inverse model of an ideal power amplifier, so that the inverse model outputs a second output signal. The error is calculated by subtracting the second output signal from the intermediate signal.

According to the linearization method described above, the step of performing the fuzzy statistics on the input signal and the error includes the following steps. The input signal is converted into a first value between 0 and 1. The error is converted into a second value between 0 and 1.

According to the linearization method described above, the step of calculating the compensation value according to the fuzzy control table and the defuzzification equation includes the following steps. A first field is found that includes the first value in the input signal field of the fuzzy control table. A second field is found that includes the second value in the error field of the fuzzy control table. A third field is found at the intersection of the first field and the second field. The third field includes a third value, which is equal to the minimum of the first value and the second value. The third value is substituted into the defuzzification equation to calculate the compensation value.

According to the linearization method described above, the defuzzification equation is

$$C V = \frac{{Σ}_{i = 1}^{n} {x}_{i} {μ}_{i} ( x )}{{Σ}_{i = 1}^{n} \vert {μ}_{i} ( x ) \vert} \cdot u .$$

CV is the compensation value; |μᵢ(x)| is the absolute value of a sampling percentage; xᵢμᵢ(x) is the product of the third value and the sampling percentage; and u is the input signal.

According to the linearization method described above, the step of calculating the error includes the following step: The second output signal is subtracted from the intermediate signal to obtain the error, which represents nonlinear components or interference of the power amplifier.

The linearization method further includes the following step. The inverse model of the ideal power amplifier is calculated. The inverse model of the ideal power amplifier is equal to the inverse function of the linear components of the power amplifier.

The linearization method further includes the following step. The error is filtered.

An embodiment of the disclosure also provides an electronic device. The electronic device includes a controller, a power amplifier, an inverse model of an ideal power amplifier, and a subtractor. The controller receives an input signal and an error associated with the input signal, performs fuzzy statistics on the input signal and the error, calculates a compensation value according to a fuzzy control table and a defuzzification equation, combines the compensation value with the input signal to obtain an intermediate signal, and outputs the intermediate signal. The power amplifier is electrically connected to the controller. The power amplifier receives the intermediate signal, and amplifies the intermediate signal to generate a first output signal. The power amplifier feeds the first output signal from the power amplifier back into the inverse model of the ideal power amplifier, so that the inverse model outputs a second output signal. The subtractor is electrically connected to the controller and the inverse model. The subtractor obtains the error through calculation: specifically, it subtracts the second output signal from the intermediate signal.

According to the electronic device described above, the controller performs fuzzy statistics on the input signal and the error by converting the input signal into a first value between 0 and 1, and converting the error into a second value between 0 and 1.

According to the electronic device described above, the controller finds a first field that includes the first value in the input signal field of the fuzzy control table. The controller finds a second field that includes the second value in the error field of the fuzzy control table. The controller finds a third field at the intersection of the first field and the second field. The third field includes a third value, which is equal to the minimum of the first value and the second value. The controller substitutes the third value into the defuzzification equation to calculate the compensation value.

According to the electronic device described above, the defuzzification equation is

$$CV = \frac{{Σ}_{i = 1}^{n} {x}_{i} {μ}_{i} ( x )}{{Σ}_{i = 1}^{n} \vert {μ}_{i} ( x ) \vert} \cdot u .$$

CV is the compensation value; |μᵢ(x)| is the absolute value of a sampling percentage; xᵢμᵢ(x) is the product of the third value and the sampling percentage; and u is the input signal.

According to the electronic device described above, the subtractor subtracts the second output signal from the intermediate signal to obtain the error. The error represents nonlinear components or interference of the power amplifier.

According to the electronic device described above, the controller calculates the inverse model of the ideal power amplifier. The inverse model of the ideal power amplifier is equal to the inverse function of the linear components of the power amplifier.

The electronic device further includes a filter and an adder. The filter is electrically connected to the controller and the subtractor, and filters the error. The adder is electrically connected between the controller and the power amplifier. The adder combines the compensation value with the input signal to obtain the intermediate signal and outputs the intermediate signal.

### BRIEF DESCRIPTION OF THE DRAWINGS

The disclosure can be more fully understood by reading the subsequent detailed description and examples with references made to the accompanying drawings.

FIG. 1 is a flow chart of a linearization method for a power amplifier in accordance with some embodiments of the disclosure.

FIG. 2 is a schematic diagram of an electronic device 200 in accordance with some embodiments of the disclosure.

FIG. 3 is a schematic diagram of a fuzzy control table 300 in accordance with some embodiments of the disclosure.

FIG. 4A and FIG. 4B are schematic diagrams of obtaining a membership function of the input signal according to the fuzzy control table 300 in FIG. 3 in accordance with some embodiments of the disclosure.

FIG. 5A and FIG. 5B are schematic diagrams of obtaining a membership function of the error according to the fuzzy control table 300 in FIG. 3 in accordance with some embodiments of the disclosure.

FIG. 6A and FIG. 6B are schematic diagrams of obtaining a membership function of output compensation according to the fuzzy control table 300 in FIG. 3 in accordance with some embodiments of the disclosure.

### DETAILED DESCRIPTION OF THE EXEMPLARY EMBODIMENTS

In order to make the above purposes, features, and advantages of some embodiments of the disclosure more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” or “include” used in the disclosure are used to indicate the existence of specific technical features, values, method steps, operations, units or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the disclosure. Regarding the drawings, the drawings show the general characteristics of methods, structures, or materials used in specific embodiments. However, the drawings should not be construed as defining or limiting the scope or properties encompassed by these embodiments. For example, for clarity, the relative size, thickness, and position of each layer, each area, or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, and “third” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the disclosure.

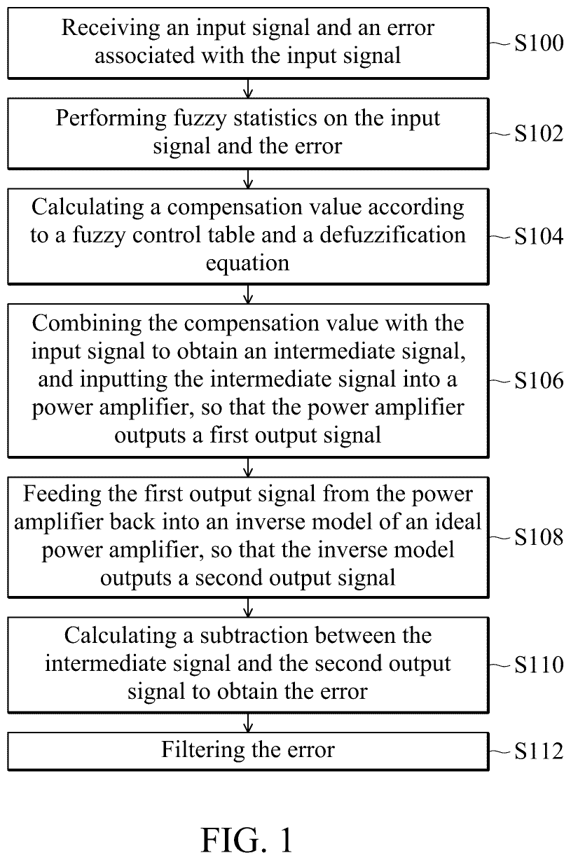

FIG. 1 is a flow chart of a linearization method for a power amplifier in accordance with some embodiments of the disclosure. As shown in FIG. 1, the linearization method for the power amplifier of the disclosure includes the following steps. An input signal and an error associated with the input signal are received (step S100). Fuzzy statistical processing is performed on the input signal and the error (step S102). A compensation value is calculated according to a fuzzy control table and a defuzzification equation (step S104). The compensation value is combined with the input signal to obtain an intermediate signal, and the intermediate signal is input into a power amplifier, so that the power amplifier outputs a first output signal (step S106). The first output signal from the power amplifier is fed back into an inverse model of an ideal power amplifier, so that the inverse model outputs a second output signal (step S108). The second output signal is subtracted from the intermediate signal to obtain the error (step S110). The error is filtered (step S112).

In some embodiments, the input signal is a radio frequency (RF) signal, but the disclosure is not limited thereto. In step S100, the error may be a feedback error filtered by the filter in step S112. In some embodiments, the error represents nonlinear components or interference of the power amplifier. In step S102, the linearization method for the power amplifier of the disclosure converts the input signal into a first value between 0 and 1, and converts the error into a second value between 0 and 1.

In step S104, the linearization method for the power amplifier of the disclosure first finds a first field that includes the first value in the input signal field of the fuzzy control table. Next, the linearization method for the power amplifier of the disclosure finds a second field that includes the second value in the error field of the fuzzy control table. The linearization method for the power amplifier of the disclosure finds a third field at the intersection of the first field and the second field. The third field includes a third value, which is equal to the minimum of the first value and the second value. Finally, the linearization method for the power amplifier of the disclosure substitutes the third value into the defuzzification equation to calculate the compensation value.

In some embodiments, the defuzzification equation in step S104 is:

$$CV = \frac{{Σ}_{i = 1}^{n} {x}_{i} {μ}_{i} ( x )}{{Σ}_{i = 1}^{n} \vert {μ}_{i} ( x ) \vert} \cdot u . \qquad ( Equation 1 )$$

In Equation 1, CV is the compensation value; |μᵢ(x) is the absolute value of a sampling percentage; xᵢμᵢ(x) is the product of the third value and the sampling percentage; and u is the input signal.

In step S106, the linearization method for the power amplifier of the disclosure subtracts the compensation value from the input signal to obtain the intermediate signal. The linearization method for the power amplifier of the disclosure inputs the intermediate signal into the power amplifier. The power amplifier amplifies the intermediate signal to obtain a first output signal. In some embodiments, the first output signal includes linear components and nonlinear components of the power amplifier.

In step S108, the linearization method for the power amplifier of the disclosure further calculates the inverse model of the ideal power amplifier. In some embodiments, the inverse model of the ideal power amplifier is equal to the inverse function of the linear components of the power amplifier. Afterwards, the linearization method for the power amplifier of the disclosure feeds the first output signal back into the inverse model of the ideal power amplifier, so that the inverse model outputs a second output signal.

In step S110, the linearization method for the power amplifier of the disclosure subtracts the second output signal from the intermediate signal to obtain the error. In detail, since the first output signal includes the linear components and the nonlinear components of the power amplifier, when the second output signal is subtracted from the intermediate signal, the linear components in the input signal and the linear components in the first input signal will cancel each other out, leaving only the nonlinear components of the power amplifier. That is, the error represents the nonlinear components or interference of the power amplifier. In step S112, the linearization method for the power amplifier of the disclosure filters the error through a filter, and then feeds the filtered error back to step S100 to complete a linearization operation of the power amplifier.

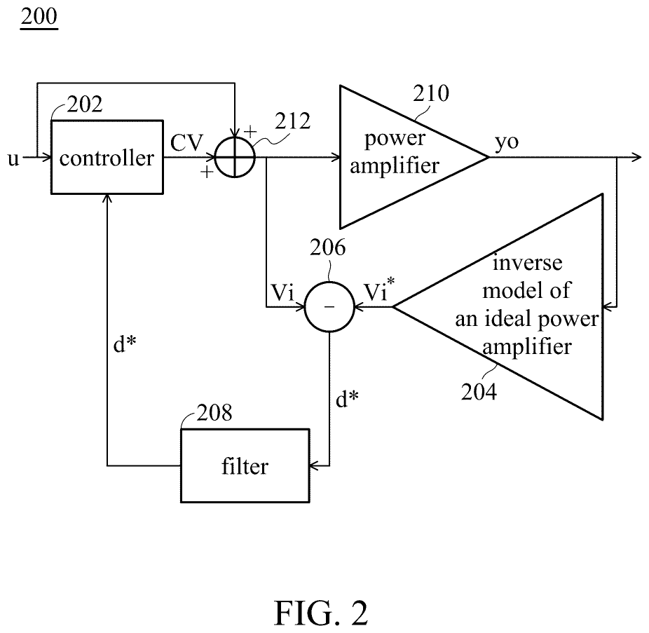

FIG. 2 is a schematic diagram of an electronic device 200 in accordance with some embodiments of the disclosure. The electronic device 200 includes a controller 202, a power amplifier 210, an inverse model 204 of an ideal power amplifier, a subtractor 206, an adder 212, and a filter 208. The controller 202 receives an input signal u and an error d* associated with the input signal u. The controller 202 performs fuzzy statistics on the input signal u and the error d*, and calculates a compensation value CV according to a fuzzy control table and a defuzzification equation. The adder 212 combines the compensation value CV with the input signal u to obtain an intermediate signal Vi, and outputs the intermediate signal Vi. The power amplifier 210 is electrically connected to the adder 212, receives the intermediate signal Vi, amplifies the intermediate signal Vi to generate a first output signal yo, and feeds the first output signal yo back to the inverse model 204 of the ideal power amplifier, so that the inverse model 204 outputs a second output signal Vi*.

The subtractor 206 is electrically connected to the adder 212 and the inverse model 204, and compares the intermediate signal Vi with the second output signal Vi* to obtain the error d*. In some embodiments, the subtractor 206 and the adder 212 are included in the controller 202, but the disclosure is not limited thereto. The subtractor 206 may calculate a subtraction between the intermediate signal Vi and the second output signal Vi* to obtain the error d*. The filter 208 is electrically connected to the controller 202 and the subtractor 206 to filter the error d* and complete the linearization operation of the power amplifier 202.

In some embodiments, the controller 202 calculates the inverse model 204 of the ideal power amplifier. The inverse model 204 of the ideal power amplifier is equal to the inverse function of the linear components of the power amplifier 210. For example, the inverse function may be P⁻¹(s), where P(s) may be a linear function and P(s)=A×Vi, wherein Vi is the intermediate signal (input of the ideal power amplifier) and A is the gain of the ideal power amplifier. A may be a constant gain.

In some embodiments, the subtractor 206 subtracts the second output signal Vi* from the intermediate signal Vi to obtain an error d*. The error d* represents the nonlinear components or interference of the power amplifier 210.

Using fuzzy statistics, the controller 202 converts the input signal u into a first value between 0 and 1, and converts the error d* into a second value between 0 and 1. The controller 202 finds a first field that includes the first value in the input signal field of the fuzzy control table. The controller 202 finds a second field that includes the second value in the error field of the fuzzy control table. The controller 202 finds a third field at the intersection of the first field and the second field. The third field includes a third value, which is equal to the minimum of the first value and the second value. The controller 202 substitutes the third value into the defuzzification equation to calculate the compensation value. The defuzzification equation may be, for example, Equation 1.

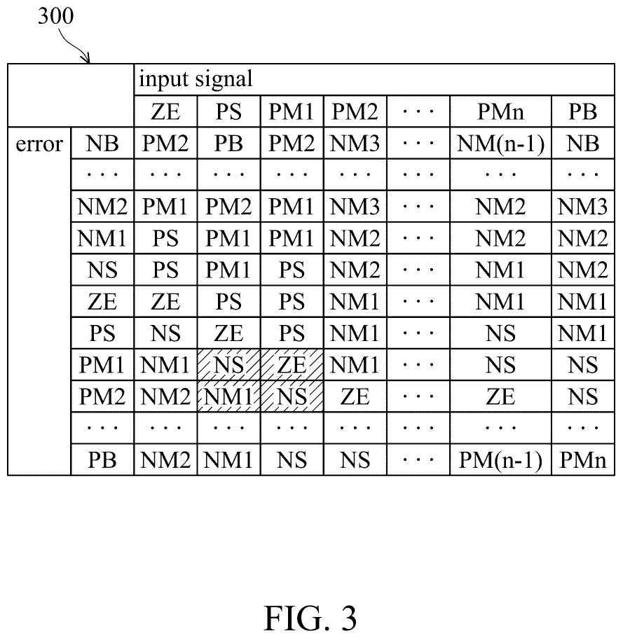

FIG. 3 is a schematic diagram of a fuzzy control table 300 in accordance with some embodiments of the disclosure. As shown in FIG. 3, the fuzzy control table 300 includes the input signal field and the error field. The input signal field may include, for example, fields ZE, PS, PM1, PM2, . . . , PMn, and PB in order from left to right. The error field may include, for example, fields NB, . . . , NM2, NM1, NS, ZE, PS, PM1, PM2, . . . , PB in order from top to bottom.

For example, the values covered by the field ZE in the input signal field and the error field may be, for example, 0%˜r_{ze}% (i.e., the membership function). The values covered by the field PS in the input signal field and the error field may be, for example, rₚₛ_{ₘ}%˜rₚₛ_{_{M}}%. The values covered by the field PM1 in the input signal field and the error field may be, for example, rₚₘ₁_{ₘ}%˜rₚₘ₁_{_{M}}%. The values covered by the field PM2 in the input signal field and the error field may be, for example, rₚₘ₂_{ₘ}%˜rₚₘ₂_{_{M}}%. The values covered by the field PMn in the input signal field and the error field may be, for example, rₚₘₙ_{ₘ}%˜rₚₘₙ_{_{M}}%. The values covered by the field PB in the input signal field and the error field may be, for example, r_{pb}_{ₘ}%˜r_{pb}_{_{M}}%.

Using fuzzy statistics, the controller 202 converts the input signal u into i % and the error d* into e %. Referring to the fuzzy control table 300, the disclosure first obtains that the conversion value i % of the input signal u is between the field PS and the field PM1, and the conversion value e % of the error d* is between the field PM1 and the field PM2. The disclosure uses the above results to calculate the percentage of each member and then maps it to the fuzzy control table 300.

In the mapping process, when the conversion value i % of the input signal u is located in the field PS, and the conversion value e % of the error d* is located in the field PM1 and field PM2, the corresponding value of the output compensation o may be located, for example, in the field NS and field NM1. When the conversion value i % of the input signal u is located in the field PM1, and the conversion value e % of the error d* is located in the fields PM1 and PM2, the corresponding value of the output compensation o may be located, for example, in the fields ZE and NS.

In some embodiments, when the conversion value i % of the input signal u is in the field PS and the conversion value e % of the error d* is in the field PM1, the value of the output compensation o is in the field NS. The value of the output compensation o is the minimum of the conversion value iₚₛ% of the input signal u and the conversion value eₚₘ₁% of the error d*. That is, oₙₛ=min(iₚₛ%, eₚₘ₁%). When the conversion value i % of the input signal u is in the field PS and the conversion value e % of the error d* is in the field PM2, the value of the output compensation o is in the field NM1. The value of the output compensation o is the minimum of the conversion value iₚₛ% of the input signal u and the conversion value eₚₘ₁% of the error d*. That is, oₙₘ₁=min(iₚₛ%, eₚₘ₁%).

In some embodiments, when the conversion value i % of the input signal u is in the field PM1 and the conversion value e % of the error d* is in the field PM1, the value of the output compensation o is in the field ZE. The value of the output compensation o is the minimum between the conversion value iₚₘ₁% of the input signal u and the conversion value eₚₘ₁% of the error d*. That is, oₙₛ=min(iₚₘ₁%, eₚₘ₁%). When the conversion value i % of the input signal u is in the field PM1 and the conversion value e % of the error d* is in the field PM2, the value of the output compensation o is in the field NS. The value of the output compensation o is the minimum between the conversion value iₚₘ₁% of the input signal u and the conversion value eₚₘ₂% of the error d*. That is, oₙₛ=min(iₚₘ₁%, eₚₘ₂%).

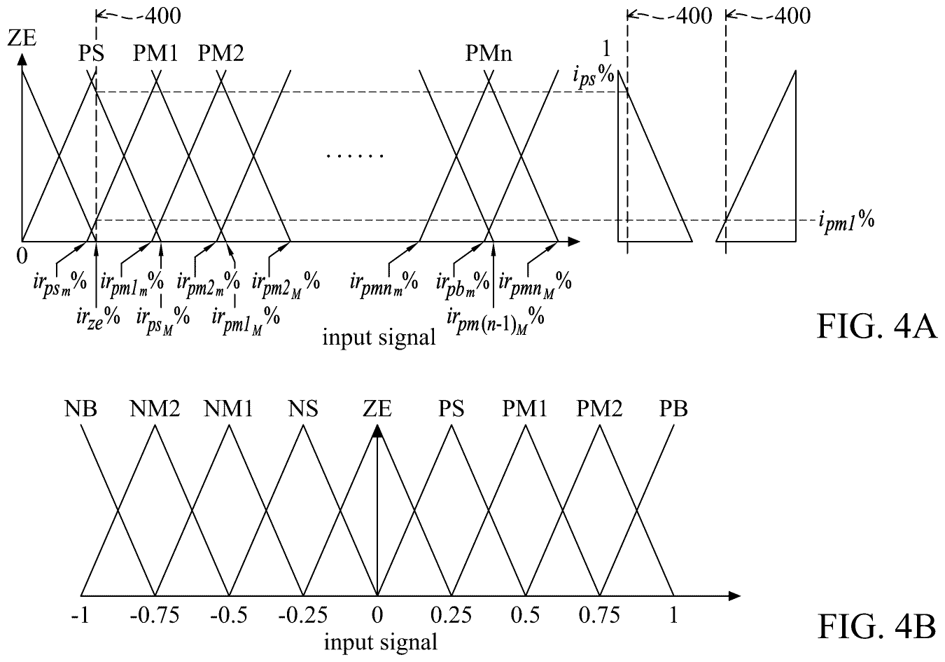

FIG. 4A and FIG. 4B are schematic diagrams of obtaining a membership function of the input signal according to the fuzzy control table 300 in FIG. 3 in accordance with some embodiments of the disclosure. The units of both the horizontal and vertical axes of FIG. 4A are percentages. For example, the horizontal axis of FIG. 4A includes 0, irₚₛ_{ₘ}%, ir_{ze}%, irₚₘ₁_{ₘ}%, irₚₛ_{_{M}}%, irₚₘ₂_{ₘ}%, irₚₘ₁_{_{M}}%, irₚₘ₂_{_{M}}% . . . , irₚₘₙ_{ₘ}%, ir_{pb}_{ₘ}%, irₚₘ₍ₙ₋₁₎_{_{M}}%, and irₚₘₙ_{_{M}}% in sequence, which correspond to the fields ZE, PS, PM1, PM2, . . . , PB, and PMn, respectively. As shown in FIG. 4A, taking a sampling point 400 as an example, since the sampling point 400 intersects both the field PS and the field PM1, the conversion values of the input signal corresponding to the sampling point 400 are iₚₛ% and iₚₘ₁%.

FIG. 4B is a schematic diagram of a membership function in practical application in accordance with some embodiments of the disclosure. The units of both the horizontal and vertical axes of FIG. 4B are percentages. As shown in FIG. 4B, the horizontal axis of FIG. 4B includes −1, −0.75, −0.5, −0.25, 0, 0.25, 0.5, 0.75, and 1 in sequence, which correspond to the fields NB, NM2, NM1, NS, ZE, PS, PM1, PM2, and PB, respectively.

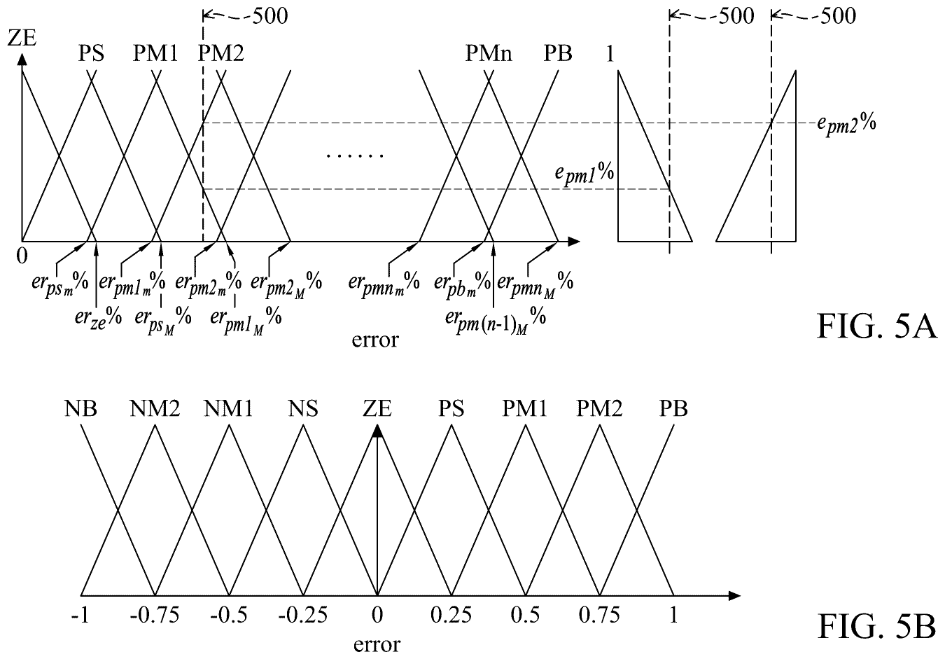

FIG. 5A and FIG. 5B are schematic diagrams of obtaining a membership function of the error according to the fuzzy control table 300 in FIG. 3 in accordance with some embodiments of the disclosure. The units of both the horizontal and vertical axes of FIG. 5A are percentages. The horizontal axis of FIG. 5A includes 0, erₚₛ_{ₘ}%, er_{ze}%, erₚₘ₁_{ₘ}% erₚₛ_{_{M}}%, erₚₘ₂_{ₘ}%, erₚₘ₁_{_{M}}%, erₚₘ₂_{_{M}}%, . . . , erₚₘₙ_{ₘ}%, er_{pb}_{ₘ}%, erₚₘ₍ₙ₋₁₎_{_{M}}%, and erₚₘₙ_{_{M}}% in sequence, which correspond to the fields ZE, PS, PM1, PM2, . . . , PMn, and PB. As shown in FIG. 5A, taking a sampling point 500 as an example, since the sampling point 500 intersects both the field PM1 and the field PM2, the conversion values of the error corresponding to the sampling point 500 are eₚₘ₁% and eₚₘ₂%.

FIG. 5B is a schematic diagram of a membership function in practical application in accordance with some embodiments of the disclosure. The units of both the horizontal and vertical axes of FIG. 5B are percentages. As shown in FIG. 5B, the horizontal axis of FIG. 5B includes −1, −0.75, −0.5, −0.25, 0, 0.25, 0.5, 0.75, and 1 in sequence, which correspond to the fields NB, NM2, NM1, NS, ZE, PS, PM1, PM2, and PB, respectively.

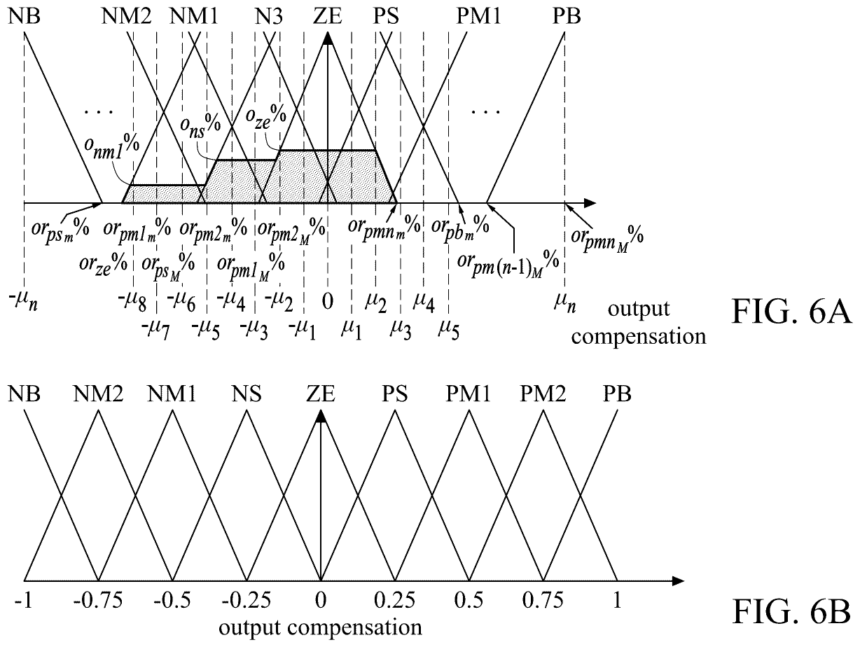

FIG. 6A and FIG. 6B are schematic diagrams of obtaining a membership function of output compensation according to the fuzzy control table 300 in FIG. 3 in accordance with some embodiments of the disclosure. The units of both the horizontal and vertical axes of FIG. 6A are percentages. The horizontal axis of FIG. 6A includes orₚₛ_{ₘ}%, or_{ze}%, orₚₘ₁_{ₘ}%, orₚₛ_{_{M}}%, orₚₘ₂_{ₘ}%, orₚₘ₁_{_{M}}%, orₚₘ₂_{_{M}}%, . . . , orₚₘₙ_{ₘ}%, or_{pb}_{ₘ}%, orₚₘ₍ₙ₋₁₎_{_{M}}%, and orₚₘₙ_{_{M}}% in sequence, which correspond to the fields NB, NM2, NM1, NS, ZE, PS, PM1, . . . , and PB. The sampling point percentages in the horizontal axis of FIG. 6A are −μₙ, −μ₈, −μ₇, −μ₆, −μ₅, −μ₄, −μ₃, −μ₂, −μ₁, 0, μ₁, μ₂, μ₃, μ₄, μ₅, μₙ respectively.

As shown in FIG. 6A, the output compensation values corresponding to the sampling point percentage −μ₈ to the sampling point percentage −μₛ are all oₙₘ_{₁}%. The output compensation values corresponding to the sampling point percentage −μ₄ to the sampling point percentage −μ₃ are all on,%. The output compensation values corresponding to the sampling point percentage −μ₂ to the sampling point percentage μ₂ are all o_{ze}%. Therefore, the output compensation values corresponding to each sampling point percentage are substituted into Equation 1 to obtain the following Equation 2, so as to obtain the compensation value CV.

$$CV = \frac{{Σ}_{i = 1}^{n} {x}_{i} {μ}_{i} ( x )}{{Σ}_{i = 1}^{n} \vert {μ}_{i} ( x ) \vert} \cdot u = ( \frac{\begin{matrix}\begin{matrix}{o}_{n m 1} * ( - {μ}_{8} ) + {o}_{n m 1} * ( - {μ}_{7} ) + \\ {o}_{n m 1} * ( - {μ}_{6} ) + {o}_{n m 1} * ( - {μ}_{5} ) +\end{matrix} \\ {o}_{n s} * ( - {μ}_{4} ) + {o}_{n s} * ( - {μ}_{3} ) + {o}_{z e} * ( - {μ}_{2} ) + {o}_{z e} * ( - {μ}_{1} )\end{matrix}}{\begin{matrix}\vert - {μ}_{8} \vert + \vert - {μ}_{7} \vert + \vert - {μ}_{6} \vert + \vert - {μ}_{5} \vert + \vert - {μ}_{4} \vert + \\ \vert - {μ}_{3} \vert + \vert - {μ}_{2} \vert + \vert - {μ}_{1} \vert + 0 + \vert {μ}_{1} \vert + \vert {μ}_{2} \vert\end{matrix}} + \frac{{o}_{z e} * 0 + {o}_{z e} * ( {μ}_{1} ) + {o}_{z e} * ( {μ}_{2} )}{\begin{matrix}\vert - {μ}_{8} \vert + \vert - {μ}_{7} \vert + \vert - {μ}_{6} \vert + \vert - {μ}_{5} \vert + \vert - {μ}_{4} \vert + \\ \vert - {μ}_{3} \vert + \vert - {μ}_{2} \vert + \vert - {μ}_{1} \vert + 0 + \vert {μ}_{1} \vert + \vert {μ}_{2} \vert\end{matrix}} ) \cdot u \qquad ( Equation 2 )$$

FIG. 6B is a schematic diagram of a membership function in practical application in accordance with some embodiments of the disclosure. The units of both the horizontal and vertical axes of FIG. 6B are percentages. As shown in FIG. 6B, the horizontal axis of FIG. 5B includes −1, −0.75, −0.5, −0.25, 0, 0.25, 0.5, 0.75, and 1 in sequence, which correspond to the fields NB, NM2, NM1, NS, ZE, PS, PM1, PM2, and PB, respectively.

The linearization method for the power amplifier and the electronic device 200 of the disclosure do not need to directly calculate the inverse function of the power amplifier as in the conventional Digital Pre-Distortion (PDP) method. The linearization method of the power amplifier of the disclosure directly regards the nonlinear components of the power amplifier as interference, so the inverse function of the power amplifier is directly calculated based on the ideal power amplifier, which greatly simplifies the difficulty of implementation.

The linearization method for the power amplifier and the electronic device 200 of the disclosure regard all parts that are not as expected as internal interference or external interference, so even if there is really the external interference or the internal interference, it also can be resolved.

The computing speed of the controller 202 in the electronic device 200 of the disclosure is much simpler than the adaptive control that needs to continuously update the weights. In most cases, only a few logical rules are needed to calculate the compensation value CV.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A linearization method for a power amplifier, comprising:
receiving an input signal and an error associated with the input signal;
performing fuzzy statistics on the input signal and the error;
calculating a compensation value according to a fuzzy control table and a defuzzification equation;
combining the compensation value with the input signal to obtain an intermediate signal, and inputting the intermediate signal into a power amplifier, so that the power amplifier outputs a first output signal;
feeding the first output signal from the power amplifier back into an inverse model of an ideal power amplifier, so that the inverse model outputs a second output signal, and
calculating a subtraction between the intermediate signal and the second output signal to obtain the error.

2. The linearization method as claimed in claim 1, wherein the step of performing the fuzzy statistics on the input signal and the error comprises:
converting the input signal into a first value between 0 and 1; and
converting the error into a second value between 0 and 1.

3. The linearization method as claimed in claim 2, wherein the step of calculating the compensation value according to the fuzzy control table and the defuzzification equation comprises:
finding a first field that comprises the first value in an input signal field of the fuzzy control table;
finding a second field that comprises the second value in an error field of the fuzzy control table;
finding a third field at an intersection of the first field and the second field; wherein the third field comprises a third value, which is equal to a minimum of the first value and the second value; and
substituting the third value into the defuzzification equation to calculate the compensation value.

4. The linearization method as claimed in claim 3, wherein the defuzzification equation is
$$CV = \frac{{Σ}_{i = 1}^{n} {x}_{i} {μ}_{i} ( x )}{{Σ}_{i = 1}^{n} \vert μ {i}_{} ( x ) \vert} \cdot u$$
wherein CV is the compensation value; [symbol] |μ [symbol] _i(x)| is an absolute value of a sampling percentage; xᵢμᵢ(x) is a product of the third value and the sampling percentage; and u is the input signal.

5. The linearization method as claimed in claim 1, wherein the step of calculating the subtraction between the intermediate signal and the second output signal to obtain the error, comprises:
subtracting the second output signal from the intermediate signal to obtain the error;
wherein the error represents nonlinear components or interference of the power amplifier.

6. The linearization method as claimed in claim 1, further comprising:
calculating the inverse model of the ideal power amplifier;
wherein the inverse model of the ideal power amplifier is equal to an inverse function of linear components of the power amplifier.

7. The linearization method as claimed in claim 1, further comprising:
filtering the error.

8. An electronic device, comprising:
a controller, configured to receive an input signal and an error associated with the input signal, perform fuzzy statistics on the input signal and the error, calculate a compensation value according to a fuzzy control table and a defuzzification equation, combine the compensation value with the input signal to obtain an intermediate signal, and output the intermediate signal;
a power amplifier, electrically connected to the controller, configured to receive the intermediate signal, and amplify the intermediate signal to generate a first output signal;
an inverse model of an ideal power amplifier; wherein the power amplifier is configured to feed the first output signal from the power amplifier back into the inverse model of the ideal power amplifier, so that the inverse model outputs a second output signal; and
a subtractor, electrically connected to the controller and the inverse model, configured to calculate a subtraction between the intermediate signal and the second output signal to obtain the error.

9. The electronic device as claimed in claim 8, wherein the controller is configured to perform fuzzy statistics on the input signal and the error by converting the input signal into a first value between 0 and 1, and converting the error into a second value between 0 and 1.

10. The electronic device as claimed in claim 9, wherein the controller is configured to find a first field that comprises the first value in the input signal field of the fuzzy control table; the controller is configured to find a second field that comprises the second value in the error field of the fuzzy control table; the controller is configured to find a third field at the intersection of the first field and the second field; wherein the third field comprises a third value, which is equal to the minimum of the first value and the second value; and the controller is configured to substitute the third value into the defuzzification equation to calculate the compensation value.

11. The electronic device as claimed in claim 10, wherein the defuzzification equation is
$$CV = \frac{{Σ}_{i = 1}^{n} {x}_{i} {μ}_{i} ( x )}{{Σ}_{i = 1}^{n} \vert μ {i}_{} ( x ) \vert} \cdot u$$
wherein CV is the compensation value; [symbol] |μ [symbol] _i(x)| is an absolute value of a sampling percentage; xᵢμᵢ(x) is a product of the third value and the sampling percentage; and u is the input signal.

12. The electronic device as claimed in claim 8, wherein the subtractor is configured to subtract the second output signal from the intermediate signal to obtain the error; wherein the error represents nonlinear components or interference of the power amplifier.

13. The electronic device as claimed in claim 8, wherein the controller is configured to calculate the inverse model of the ideal power amplifier; wherein the inverse model of the ideal power amplifier is equal to the inverse function of the linear components of the power amplifier.

14. The electronic device as claimed in claim 8, further comprising:
a filter, electrically connected to the controller and the subtractor, configured to filter the error; and
an adder, electrically connected between the controller and the power amplifier, configured to combine the compensation value with the input signal to obtain the intermediate signal and output the intermediate signal.
